(19) United States
(12) Patent Application Publication
(10) Pub. No.: US 2021/0034795 A1
(43) Pub. Date: Feb. 4, 2021

(54) GENERATING A LAYOUT FOR A TRANSPORTATION SYSTEM

(71) Applicant: HYPERLOOP TECHNOLOGIES, INC., Los Angeles, CA (US)

(72) Inventors: Dapeng Zhang, Los Angeles, CA (US); Yanning Li, Los Angeles, CA (US); Joshua Raycroft, Los Angeles, CA (US); Jerome Wei, Los Angeles, CA (US)

(21) Appl. No.: 16/945,566

(22) Filed: Jul. 31, 2020

Related U.S. Application Data
(60) Provisional application No. 62/881,565, filed on Aug. 1, 2019.

(51) Int. Cl. G06F 30/13; G06F 16/901; B61B 13/10; B61B 13/08

(52) U.S. Cl. CPC G06F 30/13; B61B 13/08; B61B 13/10; G06F 16/9024

(57) ABSTRACT

Generating a layout for a transportation system. A method is provided. The method includes determining a set of destinations for a transportation system that uses a first transportation technology. The method also includes determining a set of routes. The method further includes generating a graph based on the destinations and routes. The graph comprises a set of nodes that represent the destinations. The graph further comprises a set of edges that represent a first subset of the set of routes. The set of edges are associated with a set of costs. Each cost of the set of costs represents a respective travel time when the first transportation technology is used. The method further includes updating the graph based on a second set of costs. Each cost of the set second of costs represents a respective travel time when a second transportation technology is used. The method further includes generating a layout for the transportation system based on the graph.

### CROSS-REFERENCE TO RELATED APPLICATIONS

This application claims the benefit of U.S. Provisional Patent Application No. 62/881,565, filed on Aug. 1, 2019. The disclosure of the above-referenced application is hereby incorporated by reference in its entirety.

### TECHNICAL FIELD

Aspects of the present disclosure relate to a transportation system, and more particularly, to generating a layout for a transportation system.

### BACKGROUND

Transportation systems may include multiple transportation lines and multiple transportation pods that travel along the various transportation lines. The transportation lines may be directed or directional routes that allow transportation pods (e.g., vehicles) to travel between different locations in the transportation system. For example, a transportation line may be similar to links, tracks, or rails that allow transportation pods to travel to different locations (e.g., stops, stations, etc.) within the transportation system. The transportation pods may be capsules, vehicles, cars, cabs, or some other type of device that may move from one location to another. For example, the transportation pods may be similar to trains, although the transportation pods may not travel on tracks. The transportation pods may transport various things between the stops in the transportation system 100. For example, the transportation pods may transport (e.g., move, convey, etc.) passengers or items, such as products, goods, freight, merchandise, payloads, shipments, packets, etc., between different stops in the transportation system.

### BRIEF DESCRIPTION OF THE DRAWINGS

The described embodiments and the advantages thereof may best be understood by reference to the following description taken in conjunction with the accompanying drawings. These drawings in no way limit any changes in form and detail that may be made to the described embodiments by one skilled in the art without departing from the spirit and scope of the described embodiments.

FIG. 1 is a block diagram that illustrates an example transportation system, in accordance with one embodiment of the present disclosure.

FIG. 2 is a block diagram that illustrates an example transportation system, in accordance with one embodiment of the present disclosure.

FIG. 3 is a block diagram that illustrates an example planning module, in accordance with one embodiment of the present disclosure.

FIG. 4 is a diagram illustrating example pseudocode which represents operations that may be performed by a planning module and/or an updating module, in accordance with one embodiment of the present disclosure.

FIG. 5 is a diagram illustrating example pseudocode which represents operations that may be performed by a planning module and/or an updating module, in accordance with one embodiment of the present disclosure.

FIG. 6 is a flow diagram of a process of generating a layout for a transportation system, in accordance with one embodiment of the present disclosure.

FIG. 7 is a block diagram of an example computing device that may perform one or more of the operations described herein, in accordance with one embodiment of the present disclosure.

### DETAILED DESCRIPTION

As discussed above, transportation systems may include multiple transportation lines and multiple transportation pods that travel along the various transportation lines. The transportation pods may be capsules, vehicles, cars, or some other type of device that may move from one location to another. The transportation pods may transport various things between the stops in the transportation system. For example, the transportation pods may transport (e.g., move, convey, etc.) passengers or items, such as products, goods, freight, merchandise, payloads, shipments, packets, etc., between different stops in the transportation system. The transportation lines may be connected via junctions that allow transportation pods to merge from one transportation line to another.

A transportation system may span hundreds or thousands of miles. For example, a transportation system may span states, countries, provinces, the North American continent, the European continent, the Asian continent, etc. Thus, the transportation system may include hundreds if not thousands of destinations. For example, the major cities in each state of the United States may be destinations in a transportation system that spans the United States. The infrastructure associated with a transportation may be expensive and/or may be time-consuming to build, construct, etc. In addition, maintenance of the infrastructure may also be expensive. Thus, it may be useful to carefully plan the layout of the transportation system. The layout of the transportation system may refer to the destinations and the transportations lines that interconnect the different destinations. For example, some destinations may be directly connected by a transportation line while other destinations may be indirectly connected via transportation lines that go through other destinations. In addition, it is also useful to keep the travel times between destinations below a threshold. For example, the travel time between two destinations, whether the two destinations are directly connected or not, should be below a threshold time or constraint.

The present disclosure may use graphs that include nodes which represent the destinations of the transportation system and edges which represent possible transportation lines that may be included in the transportation system. Each edge is associated with a cost that represents a travel time between two destinations when a first transportation technology is used. The graph is analyzed and edges are added, removed, and/or replaced based on a second set of costs (e.g., a set of constraints/thresholds). The second set of costs are based on a second transportation technology that may have a slower speed than the first transportation technology.

Generating, determining, planning, etc., the layout for the transportation system may be a difficult and time consuming task. For example, applications, methods, algorithms, etc., may generate a layout for the transportation in an exponential running time because the problem of generating the layout may be an NP-hard problem. By using the systems, modules, and methods described herein, the time and/or effort for generating, determining, planning, etc., the layout for the transportation system may be decreased. For example, the layout for the transportation system may be generated in a polynomial running time. In addition, the process for generating, determining, planning, etc., the layout for the transportation system may be automated. Furthermore, the costs for building and/or maintaining the transportation may be decreased because the number of transportation lines may be reduced while still keeping the travel times between destinations below a threshold/constraint.

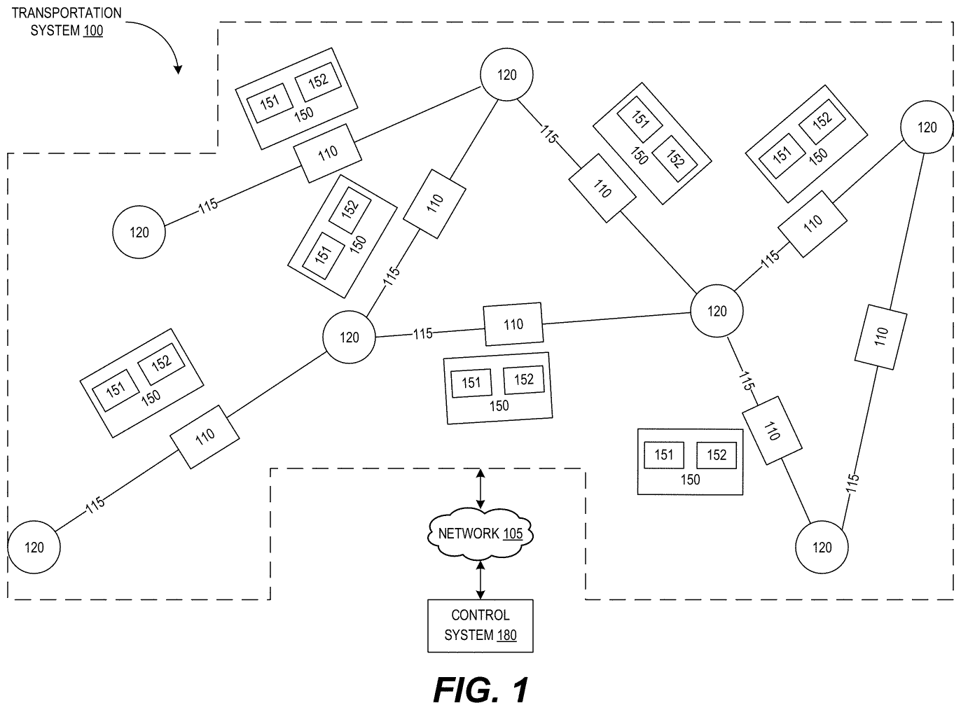

FIG. 1 is a block diagram that illustrates an example transportation system 100, in accordance with one embodiment of the present disclosure. The transportation system 100 includes transportation pods 110, transportation lines 115, and destinations 120. As discussed above, the transportation lines 115 may be directed or directional paths that allow transportation pods 110 (e.g., vehicles) to travel between the different destinations 120. For example, the transportation lines 115 may be similar to links, tracks, or rails that allow transportation pods 110 to travel to different locations (e.g., destinations 120) within the transportation system 110. In one embodiment, the transportation lines 115 may be tubes within which the transportation pods 110 may travel. For example, the transportation lines 115 may be vacuum sealed (or near vacuum sealed) tubes that include magnetic (e.g., electromagnetic) tracks. Different transportation lines 115 may be connected to each other via junctions between the transportation lines. A junction may be a location where two transportation lines converge or diverge. For example, a junction may allow a transportation pod 110 on a first transportation line to merge onto a second transportation line.

The transportation pods 110 may each be capsules, vehicles, cars, or some other type of device that may move from one location to another. For example, the transportation pods 110 may be similar to trains, although the transportation pods 110 may not travel on tracks. In one embodiment, transportation pods 110 may be a magnetic levitation (maglev) pod or capsule that travels along magnetic tracks located within a tube (e.g., a vacuum sealed or low air pressure tube). The transportation pods 110 may transport various things between the stops in the transportation system 100. For example, the transportation pods 110 may transport (e.g., move, convey, etc.) passengers between different stops in the transportation system 100. In another example, the transportation pods 110 may transport items, such as products, goods, freight, merchandise, payloads, shipments, packets, etc., between different stops in the transportation system. The transportation pods 110 may include multiple portions (e.g., multiple pods that are logically grouped or physically coupled together). The length of each of the transportation pods 110 may vary based on the needs or requirements of the transportation system 100 (e.g., may vary from less than ten meters to hundreds of meters). Transportation pods 110 may each include one or more of a light detection and ranging (LiDAR) device, a laser range finder, a camera (e.g., a video camera), a radio frequency device (e.g., a radar device), an ultrasonic sensor, etc, and/or other device that may be used for autonomous navigation and/or operation of the transportation pods 110.

The destinations 120 may be stops, stations, waypoints, etc., where passengers and/or cargo may be loaded onto the transportation pods 110. For example, the destinations 120 may be different cities, towns, metropolitan areas, etc., that are interconnected by the transportation lines 115. Although the present disclosure may refer to cities, towns, and/or metropolitan areas, the destinations 120 may be any location where a transportation 110 may stop (e.g., temporarily stop to load/unload passengers and/or cargo). For example, the destinations 120 may be stops (e.g., stations) within one city.

The infrastructure nodes 150 may be devices, systems, mechanisms, etc., that allow the transportation system 100 to detect, communicate with, and manage the transportation pods 110. The infrastructure nodes 150 may be positioned at various locations along the transportation lines 115. For example, there may be an infrastructure node 150 located every 10 meters, 50 meters, 100 meters, or some other appropriate distance along each of the transportation lines 115. The infrastructure nodes 150 may be placed at known or predetermined locations along the transportation lines 115 (e.g., the geographical locations of the infrastructure nodes 150 are known).

An infrastructure node 150 includes a sensor node 151. The sensor node 151 may include various devices, systems, mechanisms, etc., that allow the infrastructure node 150 to detect the location and/or speed of the transportation pods 110 as they travel through the transportation lines 115. For example, the sensor node 151 may include one or more of a radio frequency device (e.g., a radar system), a laser range finder, a camera (e.g., a video camera), an ultrasonic sensor, a Hall effect sensor, a presence sensor/detector (e.g., a device to detect the presence of a transportation pod 110), etc., that may be used to detect the speed of the transportation pods 110. Because the location of an infrastructure node 150 is known, the sensor node 151 allows an infrastructure node 150 to determine one or more of the speed and acceleration of a transportation pod at a certain point or location along a transportation line. The sensor node 151 may also be able to identify a transportation pod. For example, the sensor node 151 may include a radio-frequency identification (RFID) reader which may read an RFID tag located on a transportation pod. In another example, the sensor node 151 may determine an identifier for a transportation pod based on communications (e.g., messages) exchanged with the transportation pod via communication node 152.

An infrastructure node 150 also includes a communication node 152. The communication node 152 may allow the infrastructure node to communicate with one or more of a control system (e.g., a main control system, a command and control center, etc.), transportation pods 110, and other infrastructure nodes 150. For example, the communication node 152 may include a network interface (e.g., a wired network interface, a wireless network interface, etc.) that allows the infrastructure node 150 to communicate data (e.g., transmit and receive messages, packets, frames, etc.). Various communication protocols and technologies (e.g., cellular communications systems, Wi-Fi, Bluetooth, etc.) may be used by the communication node 152 to communicate data. The communication node 152 may communicate data about a transportation pod detected by a sensor node 151. For example, the transportation pod 110 passes an infrastructure node 150, the sensor node 151 may determine an identifier for the transportation pod 110 (e.g., a name, a serial number, a car number, etc.) and may determine the speed or acceleration of the transportation pod 110. The speed or acceleration of the transportation pod 110 may be referred to as movement information. The communication node 152 may transmit the movement information to other infrastructure nodes 150 or a control system, as discussed in more detail below.

The transportation system 100 also includes a control system 180. The control system 180 may control, manage, and monitor the operation of the transportation pod 110, as discussed in more detail below. The transportation system 100 may further include infrastructure nodes 150, as discussed in more detail below. Each infrastructure node 150 may include a sensor node 151 and a communication node 152. In one embodiment, the transportation system 100 may be a closed transportation system where the addition and removal of transportation pods within the transportation system 100 is controlled (e.g., controlled or managed by the control system 180).

The control system 180 and the infrastructure nodes 150 may be interconnected or coupled to each other (e.g., communicatively coupled) via a network 105. The network 105 may carry communications (e.g., data, message, packets, frames, other appropriate types or formats of data, etc.) between the infrastructure nodes and the control system 180. The network 105 may be a public network (e.g., the Internet), a private network (e.g., a local area network (LAN) or wide area network (WAN)), or a combination thereof In one embodiment, the network 105 may include a wired or a wireless infrastructure, which may be provided by one or more wireless communications systems, such as a wireless fidelity (Wi-Fi) hotspot connected with the network and/or a wireless carrier system that can be implemented using various data processing equipment, communication towers (e.g. cell towers), etc. The transportation pods 110 may also be connected to each other, the infrastructure nodes 150, and the control system 180 via the network 105.

Each transportation pod 110 may include a pod control module (not illustrated in FIG. 1). In one embodiment, the pod control module may control the operation of a transportation pod 110. For example, the pod control module may increase or decrease the speed of the transportation pod 110, may cause a transportation pod 110 to stop at a station (e.g., a destination 120), etc. In another example, the pod control module may cause a transportation pod 110 to merge from one transportation line 115 to another transportation line 115 at a junction between the two transportation lines 115.

The pod control module of a transportation pod 110 may communicate with other transportation pods 110 (e.g., other pod control modules). For example, the pod control module may transmit the current speed and location of a transportation pod 110 to another transportation pod 110. This may be referred to as vehicle-vehicle (V-V) communications. The pod control module may also communicate with the infrastructure nodes 150. For example, the pod control module may transmit the current speed and location of the transportation pod 110 to the in structure nodes 150. This may be referred to as vehicle-infrastructure (V-I) communications. The pod control module may also transmit and/or receive messages or other data with other transportation pods 110 via the infrastructure nodes 150 (e.g., the messages/data may be forwarded by the infrastructure nodes 150). This may be referred to as vehicle-infrastructure-vehicle (V-I-V) communications.

In some embodiments, the pod control module of a transportation pod 110 may operate in conjunction and/or coordination with the control system 180 to control the operation of the transportation pod 110. For example, the control system 180 may communicate with the pod control module of a transportation pod 110 and inform the pod control module of other transportation pods 110 in the vicinity of a junction. The pod control module may increase/decrease the speed of the transportation pod to allow the transportation pod to merge safely via the junction.

In other embodiments, the control system 180 may control the operation of the transportation pods 110. For example, the control system 180 may determine when a transportation pod 110 should increase/decrease speed, should merge from one transportation line 115 to another transportation line 115, etc. The control system 180 may transmit messages or instructions to the control modules of the transportation pods 110 to cause the transportation pods to increase speed, decrease speed, merge, etc.

Each of the pod control modules and the control system 180 may include one or more computing devices. A computing device may include hardware such as processing devices (e.g., processors, central processing units (CPUs), memory (e.g., random access memory (RAM), storage devices (e.g., hard-disk drive (HDD), solid-state drive (SSD), etc.), and other hardware devices (e.g., sound card, video card, etc.). A computing device may include any suitable type of device or machine that has a programmable processor including, for example, server computers, desktop computers, laptop computers, tablet computers, smartphones, etc. In some examples, a computing device may include a single machine or may include multiple interconnected machines (e.g., multiple servers configured in a cluster).

In one embodiment, the pod control modules and the control system 180 may also include one or more virtual machines (VMs). A VM may be a software implementation of a machine (e.g., a software implementation of a computing device) that includes its own operating system (referred to as a guest OS) and executes application programs, applications, software. A VM may execute on a hypervisor which executes on top of the OS for a computing device (referred to as a host OS). The hypervisor may also be referred to as a virtual machine monitor (VMM). The hypervisor may manage system resources, including access to hardware devices such as physical processing devices (e.g., processors, CPUs, etc.), physical memory (e.g., RAM), storage device (e.g., HDDs, SSDs), and/or other devices (e.g., sound cards, video cards, etc.). The hypervisor may also emulate the hardware (or other physical resources) which may be used by the VMs to execute software/applications.

In one embodiment, the pod control modules and the control system 180 may also include one or more containers. A container may be an isolated set of resources allocated to executing an application, software, and/or process independent from other applications, software, and/or processes. A container may execute on a container engine which executes on top of the OS for a computing device. The host OS (e.g., an OS of the computing device) may use namespaces to isolate the resources of the containers from each other. The container may share the kernel, libraries, and binaries of the host OS with other containers that are executing on the computing device. The container engine may allow different containers to share the host OS (e.g., the OS kernel, binaries, libraries, etc.) of a computing device. The container engine may also facilitate interactions between the container and the resources of the computing device.

As discussed, generating, determining, planning, etc., the layout for the transportation system may be a difficult and time consuming task. For example, a user may manually add edges, remove edges, and replace edges in a graph to determine whether the transportation system may satisfy timing constraints. This process of updating the edges in the graph may be time consuming and may be prone to error. By using the systems, modules, and method described herein, the time and/or effort for generating, determining, planning, etc., the layout for the transportation system may be decreased. In addition, the process for generating, determining, planning, etc., the layout for the transportation system may be automated which may reduce the time and/or effort to generate a layout for the transportation system.

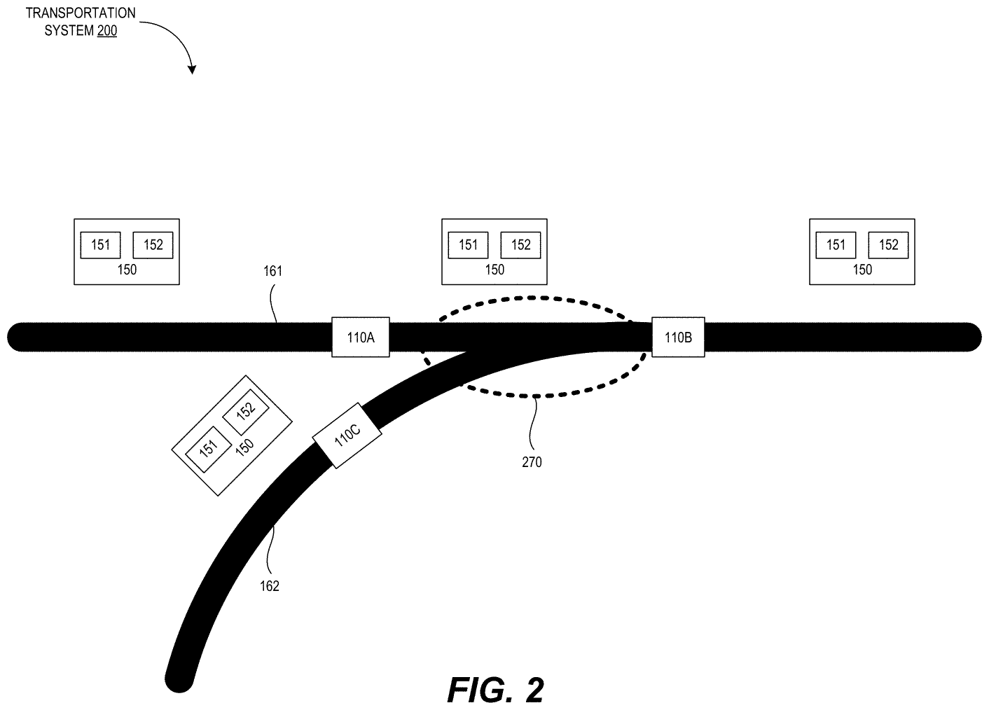

FIG. 2 is a block diagram that illustrates an example transportation system 200, in accordance with one embodiment of the present disclosure. The transportation system 200 includes a transportation line 161 and a transportation line 162. The transportation system 200 also includes infrastructure nodes 150. Each infrastructure node 150 may include a sensor node 151 and a communication node 152. The transportation system 200 further includes transportation pod 110A, transportation pod 110B, and transportation pod 110C. In one embodiment, the transportation system 200 may be a closed transportation system where the addition and removal of transportation pods within the transportation system 200 is controlled. For example, a control system (not illustrated in FIG. 1) may control the addition and removal of transportation pods within the transportation system 200.

The transportation line 161 and the transportation line 162 may each be directed or directional routes that allow transportation pods 110A, 110B, and 110C to travel between different locations in the transportation system. For example, the transportation line 161 and the transportation line 162 may be similar to links, tracks, or rails that allow transportation pods 110A, 110B, and 110C to travel to different locations (e.g., stops, stations, etc.) within the transportation system. The transportations lines 161 and 162 may be a subset of the transportation lines within the transportation system 200. For example, the transportation system 200 may include tens, hundreds, thousands, or some other appropriate number of transportation lines in other embodiments. In one embodiment, the transportation lines 161 and 162 may be tubes within which the transportation pods 110A, 110B, and 110C may travel. For example, the transportation lines 161 and 162 may be vacuum sealed (or near vacuum sealed) tubes that include magnetic (e.g., electromagnetic) tracks.

As discussed above, the transportation pods 110A, 110B and 110C may each be capsules, vehicles, cars, or some other type of device that may move from one location to another. In one embodiment, transportation pods 110A, 110B, and 110C may be a magnetic levitation (maglev) pod or capsule that travels along magnetic tracks located within a tube (e.g., a vacuum sealed or low air pressure tube). The transportation pods 110A, 110B, and 110C may transport various things between the stops in the transportation system 200. The transportation pods 110A, 110B, and 110C may include multiple portions (e.g., multiple pods that are logically grouped or physically coupled together). The length of each of the transportation pods 110A, 110B, and 110C vary in different embodiments. Also as discussed above, the infrastructure nodes 150 may be devices, systems, mechanisms, etc., that allow the transportation system 200 to detect, communicate with, and manage the transportation pods 110A, 110B, and 110C. The infrastructure nodes 150 may be positioned at various locations along the transportation lines 161 and 162.

The transportation system 200 also includes a junction 270. A junction may be a location where two transportation lines converge or diverge. For example, junction 270 may be a location where the transportation line 162 converges or merges with transportation line 161. As illustrated in FIG. 1, transportation pod 110C may be merging onto transportation line 161 from transportation line 162 via the junction 270. The junction 270 (and other junctions in the transportation system 200) may allow for cross-line operation in the transportation system 200.

Cross-line operation allows a transportation pod move across or use multiple transportation lines. Cross-line operation may provide various benefits to the transportation system 200. For example, it may reduce the number of transfers that a passenger or cargo makes when traveling to a destination. Rather than stopping at a station or stop on a first transportation line and moving to a different transportation pod on another transportation line, it would be quicker and more efficient to allow the same transportation pod to merge from the first transportation line to the second transportation line (e.g., to cross transportation lines). Cross-line operation may also allow line based (e.g., track or tubed based) transportation systems to become a more preferred mode of transportation or deliver of parcels (e.g., cargo, packages, bags, containers, etc.). This may divert passengers and cargo from congested roads to public transportation.

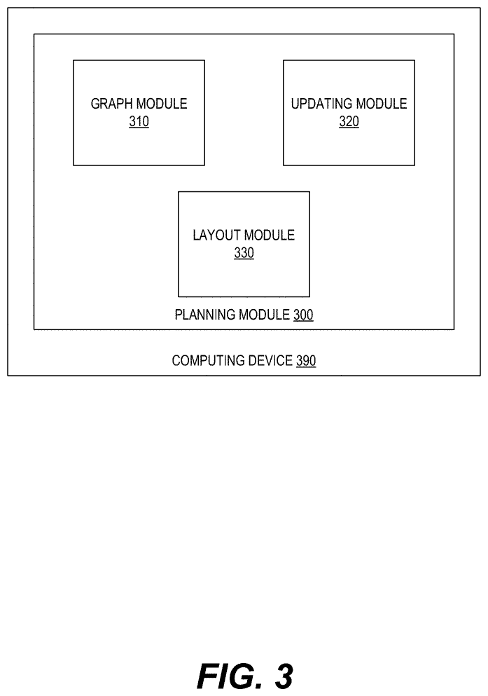

FIG. 3 is a block diagram that illustrates an example planning module 300, in accordance with one embodiment of the present disclosure. The planning module 300 may be part of a computing device 390 (e.g., a server computer, a desktop computer, a laptop computer, etc.). The planning module 300 includes a graph module 310, an updating module 320, and a layout module 330. The planning module 300 may generate a layout for a transportation system by processing and/or analyzing a graph that represents the destinations of the transportation system and/or the possible transportation lines that may be included in the transportation system. Some or all of modules 300-330 may be implemented in software, hardware, or a combination thereof. For example, one or more of modules 300-330 may be installed in persistent storage device, loaded into memory, and executed by one or more processors (not shown). In another example, one or more of modules 300-330 may be processing devices, such as an application specific integrated circuit (ASIC), a field programmable gate array (FPGA), etc. Some of modules 300-330 may be integrated together as an integrated module (e.g., a single module). In addition, some of modules 300-330 may be located in difference computing devices (e.g., different server computers).

In one embodiment, the graph module 310 may determine a set of destinations for a transportation system (e.g., for a maglev transportation system, for a Hyperloop system, etc.). The graph module may also determine a set of routes between the set of destinations for the transportation system. For example, the graph module 310 may receive user input indicating the destinations and/or routes for the transportation system via a user interface (e.g., a graphical user interface (GUI), a command line interface (CLI), etc.). In example, the graph module 310 may access and/or receive a file, message, etc., that may indicate the destinations and/or routes for the transportation system.

In one embodiment, the graph module 310 may generate a graph based on the set of destinations and/or the set of routes. The graph may include a set of nodes and edges that interconnect the nodes. The nodes may represent the set of destinations. The edges between the nodes may represent routes and/or portions or routes between the destinations. A route between two destinations (e.g., two cities) may include multiple edges and may pass through one or more additional destinations. For example, a route between a first destination and a second destination may pass through a third destination. A first edge may connect the first and third destination and a second edge may connect the third destination and the second destination. The routes in the graph may be a subset of all of the possible routes between the destinations. For example, not all of the possible routes between the destinations, and thus not all of the edges, may be included in the graph.

In some embodiments, the graph module 310 may use various algorithms, operations, functions, etc., to generate the graph. For example, the graph module 310 may use Kruskal's algorithm, Prim's algorithm, etc., to generate the graph. The graph may be a minimum spanning tree (MST). The MST may be an unconstrained MST. The unconstrained MST may not meet travel time criteria, constraints, thresholds, etc., which are discussed in more detail below. Although the present disclosure may refer to a MST, other types of trees and/or graphs may be used in other embodiments. For example, a fully connected graph/tree may be generated by the graph module 310.

In one embodiment, the set of edges in the graph may be associated with a first set of costs. For example, each edge may have and/or may be associated with a cost from the first set of costs. The cost may also be referred to as a weight. A cost for an edge may indicate a respective travel time along the edge between the two destinations coupled by the edge. The travel time along the edge may be for a first transportation technology that is used by the transportation system. For example, the cost (e.g., the travel time) for each edge may represent the travel time between two destinations when a maglev or Hyperloop technology/system is used by the transportation system.

In one embodiment, the updating module 320 may update the graph based on a second set of costs that associated with the edges (e.g., the routes) of the graph. The second set of costs may indicate the travel time for between two nodes (e.g., the travel time between two destinations) when a second transportation technology is used. For example, each cost in the second set of costs may represent the travel time between two destinations when a high-speed rail technology/system is used to directly connect the two destinations (e.g., the two nodes). The second set of costs may be referred to as threshold costs, constraints, time travel constraints, etc.

In one embodiment, the constraints/thresholds (represented by the second set of costs) may be maximum allowed travel times between two destinations/nodes in a graph. For example, there may be a cost for each pair of nodes in the graph. The cost for a route in the graph between a pair of nodes should not be larger than the respective constraint (e.g., time travel constraint) directly between the pair of nodes. The second set of costs (e.g., the time travel constraints) are used by the updating module 320 to determine whether edges should be added and/or removed from the graph, as discussed in more detail below.

The maglev/Hyperloop technology may be capable of faster speeds than the high-speed rail technology. For example, a maglev pod may be capable of travelling at 1000 kilometers (km) per hour or more and a high-speed-rail train may be capable of travelling at a speed of 250 km/h. Although the present disclosure may refer to maglev/Hyperloop technology as the first transportation technology and high-speed rail technology as the second transportation technology, other types of transportations technologies may be used with the examples, implementations, and/or embodiments of the disclosure when the transportation technology is capable of faster speeds than the second transportation technology.

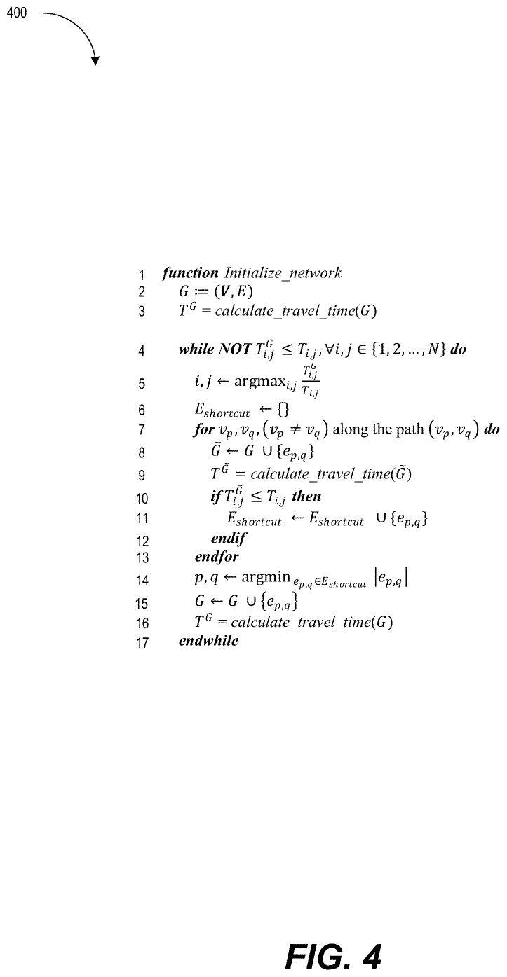

In one embodiment, the updating module 320 may update the graph by determining whether a first cost (from the first set of costs) associated with a first route is above a second cost associated with the first route. The first route may be between a first node and a second node (e.g., a first destination and a second destination). As discussed above, there may be other nodes in between the first node and the second node. For example, the route between the first node and the second node may include edges to other nodes that are between the first node and the second node. The second cost may represent the travel time for a direct route between the first node and the second node using a second transportation technology (e.g., high-speed rail technology). If the first cost of the first route is above the second cost associated with the first route, first route may not satisfy a constraint/threshold (e.g., may not satisfy a travel time constraint) and the updating module 320 may add one or more edges to the graph. The costs of the one or more edges (e.g., the total costs of the edges in the new route) that are added to the graph may be less than the second cost. Adding the one or more edges two the graph may be referred to as adding a shortcut between the first node and the second node. In one embodiment, the updating module 320 may add one or more edges to the graph based on the pseudocode 400 illustrated in FIG. 4, which is discussed in more detail below.

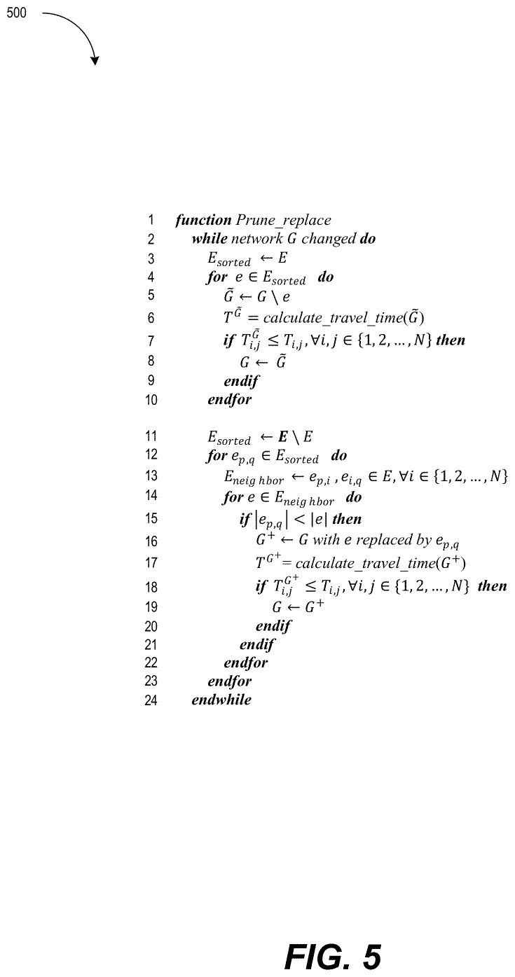

In one embodiment, the updating module 320 may determine whether a first set of edges can be removed (e.g., pruned) from the graph. For example, the updating module 320 may determine whether an edge can be removed from the graph while still satisfying the time travel constraints for each pair of nodes in the graph. If a first set of edges can be removed from the graph, the updating module 320 may remove the first set of edges from the graph. This may be referred to as pruning the graph, pruning edges, pruning, etc. In one embodiment, the updating module 320 may remove one or more edges from the graph based on the pseudocode 500 illustrated in FIG. 5, which is discussed in more detail below.

In one embodiment, the updating module 320 may determine whether a first set of edges can be replaced with a second set of edges. For example, the updating module 320 may determine whether a first edge with a higher cost can be removed and second edge with a lower cost can be added to the graph while still satisfying the time travel constraints for each pair of nodes in the graph. If the first set of edges can be replaced with the second set of edges, the updating module 320 may remove the first set of edges from the graph and may add the second set of edges to the graph. This may be referred to as replacing edge. In one embodiment, the updating module 320 may replace one or more edges from the graph based on the pseudocode 500 illustrated in FIG. 5, which is discussed in more detail below.

In one embodiment, each of the costs in the first set of costs and the second set of costs may be based on the speed of the transportation technology and the distance between two nodes. For example, the cost for an edge may be determine based on the speed of maglev pod/vehicle and/or the distance between the two nodes connected by the edge.

In one embodiment, the layout module 330 may generate a layout for the transportation system based on the graph (that was generated by the graph module 310 and updated by the updating module 320). The layout may represent a design, structure, etc., for the transportation system. For example, the layout may indicate which destinations are part of the transportation system. The layout may also indicate which destinations should be connected to each other. For example, an edge between two nodes on the graph may indicate that the corresponding destinations should be connected by a transportation line in the transportation system. The layout module 330 may indicate that a transportation line should be included between the two nodes (e.g., two cities, two stations, two stops, etc.) based on the graph. The layout module 300 may generate various output to indicate the layout for the transportation system. For example, the layout module 300 may generate a map, a file with global positioning system (GPS) coordinates, etc.

As discussed above, previous types of systems, applications, algorithms, etc., may generate a layout for a transportation system in an exponential running time. A running time may refer to the amount of time (e.g., the execution time) for an application, method, algorithms, etc., to generate an output (e.g., the layout for the transportation system). Example running times include exponential, polynomial, logarithmic, etc. In addition, manually generating the layout may be a difficult and time consuming task. In one embodiment, the planning module 300 may be able to generate the layout for the transportation system in a polynomial running time. For example, the amount of time for the planning module 300 to generate the layout may be represented using a polynomial equation. In other embodiments, the planning module 300 may be able to generate the layout for the transportation system in a running time that is less than an exponential running time. The operations of the planning module 300 (e.g., adding the additional edges or shortcut edges), removing edges, and replacing edges, as discussed above) may allow the planning module 300 to reduce and/or minimize the cost of the edges between the nodes (e.g., reduce and/or minimize the total distance of the transportation lines between the destinations) while satisfying constraints. For example, total distance of the transportation lines between the destinations may be minimized but the travel time between each pair of destinations may remain below a constraint or threshold travel time. Reducing and/or minimizing the distance between the destinations may reduce the cost of building and/or maintaining the transportation system, while allow passengers and/or cargo to reach destinations within a time constraint.

FIG. 4 is a diagram illustrating example pseudocode 400 which represents operations that may be performed by a planning module and/or an updating module, in accordance with one embodiment of the present disclosure. The operations of the pseudocode 400 may be performed by a computing device, a planning module, and/or an updating module. The pseudocode 400 may add edges to a graph, as discussed above. For example, the pseudocode 400 may add shortcuts, shortcut edges, etc. In one embodiment, the pseudocode 400 may identify shortcut edges in a greedy manner (e.g., may be referred to as a greedy algorithm). A graph G may be received and/or obtained at line 2. As discussed above, the graph G may have been previously generated using various algorithms, methods, etc., such as Prim's algorithm, Kruskal's algorithm etc. The graph G includes a set of nodes V and a set of edges that interconnect the nodes V. The nodes V may also be referred to as vertices. At line 3, the travel times for reach of the edges may be determined. As discussed above, the travel times for each of the edges may be determined using a first transportation technology (e.g., maglev/Hyperloop technology).

Lines 4-16 may analyze the travel time between each pair of nodes (e.g., destinations) and identify which travel times exceed a constraint (e.g., a time constraint). For example, the pseudocode 400 may identify a route between two destinations where the total cost of the route (e.g., the cost of the edges in the route) exceed a threshold or constraint. Line 5 may select the route that exceeds a threshold/constraint by the largest amount. The threshold/constraint may be the cost (e.g., time) for a direct edge between the two destinations when a second transportation technology (e.g., high-speed rail technology) is used.

Lines 7-12 may add edges between the two destinations which have the route that exceeds the threshold/constraint by the largest amount. For example, an edge may be added to one or more temporary graphs. If the cost (e.g., travel time) of a new route which uses the new edge is lower than the threshold/constraint, then the edge may be added to a set of possible shorts (e.g., E_{shortcut}). At line 14, the lowest cost edge (e.g., the lowest cost shortcut, the edge with the smallest travel time) is added to the graph.

In one embodiment, the edge that is added to the graph may be referred to as a shortcut, a shortcut edge, etc. A shortcut may be a direct edge between a pair of nodes (e.g., destinations) which are previously indirectly connected intermedia nodes. For all pairs of cities vᵢ, vⱼ that do not meet the travel time requirements, all shortcut candidates are explored and the edge with the lowest cost satisfying the travel time requirement is added to the graph.

The pseudocode 400 may repeat lines 4-16 until all of the routes between each pair of possible nodes (e.g., destinations) within the graph is below a respective threshold/constraint. For example, pseudocode 400 may repeat lines 4-16 until the cost for each route between each pair of nodes is below a respective constraint/threshold (which represents the travel time between the pair of nodes if the pair of nodes were directly connected using the second transportation technology).

FIG. 5 is a diagram illustrating example pseudocode 500 which represents operations that may be performed by a planning module and/or an updating module, in accordance with one embodiment of the present disclosure. The pseudocode 500 may remove edges and/or replace edges in a graph, as discussed above. In one embodiment, a graph G that is processed by the pseudocode 500 may be the graph that is generated by pseudocode 400 illustrated in FIG. 4 (e.g., may be the output of pseudocode 400). The graph G includes a set of nodes V and a set of edges E that interconnect the nodes V. The nodes V may also be referred to as vertices. Lines 2-23 be repeated by the pseudocode 500 until the no more changes are made to the graph G. For example, lines 2-23 may be repeated until the pseudocode 500 stops removing and/or adding edges to the graph G.

Line 3 may sort all of the edges in the graph in descending order by cost (e.g., travel time). For example, a list of edges that is sorted in descending order may be created. For each edge in the list, the pseudocode 500 may remove the edge and determine whether the graph G satisfies the constrains/thresholds discussed above (lines 4-9). For example, after removing an edge, the travel time between each pair of nodes (e.g., destinations) may be analyzed to determine whether the travel times exceed a constraint/threshold travel time (which is based on a direct connection between the pair of nodes using a second, slower, transportation technology). If the graph still satisfies the constraints/thresholds, then the graph is updated to remove the edge. Lines 4-9 are repeated until no more edges can be removed from the graph without violating the constrains/thresholds (e.g., time constraints).

Line 11 may sort all of the edges that are not part of the graph in descending order by cost (e.g., travel time). For example, a list of edges that are not currently part of the graph which is sorted in descending order may be created. Then for each edge in the list of edges that are not currently part of the graph, its neighboring edges (e.g., an edge that shares a node) which are currently included in the graph are explored for replacements (lines 14-21). For example, for a first edge that is not currently part of the graph, neighboring edges (e.g., edges that share a node with the first edge) are analyzed to determine if they can be replaced with the first edge. If the first edge (which is not in the graph) has a cost that is lower than the neighboring edge (which is in the graph), then pseudocode 500 creates a temporary graph where the neighboring edge is replaced with the first edge. The pseudocode 500 then determines whether the temporary graph satisfies the constraints/thresholds after the neighboring edge is replaced with the first edge (lines 17-19). If the temporary graph satisfies the constraints/thresholds after the neighboring edge is replaced with the first edge, then the neighboring edge is replaced with the first edge. Alternatively, the temporary graph may replace the previous graph in other embodiments.

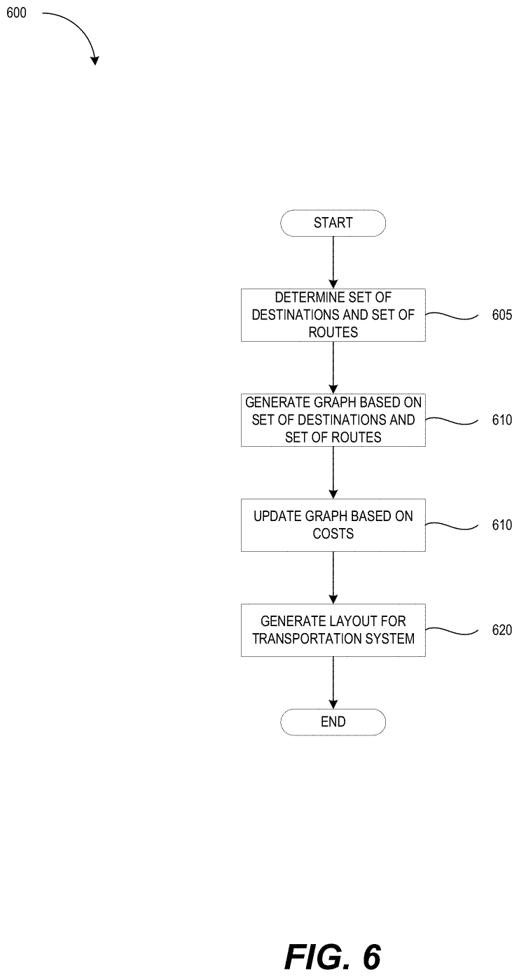

FIG. 6 is a flow diagram of a process 600 of generating a layout for a transportation system, in accordance with one embodiment of the present disclosure. Process 600 may be performed by processing logic that may comprise hardware (e.g., circuitry, dedicated logic, programmable logic, a processor, a processing device, a central processing unit (CPU), a system-on-chip (SoC), etc.), software (e.g., instructions running/executing on a processing device), firmware (e.g., microcode), or a combination thereof In some embodiments, the process 600 may be performed by one or more of a planning module and a computing device.

The process 600 begins at block 605, where the process 600 may determine a set of routes and a set of destinations for a transportation system. For example, the process 600 may receive user input, a message, a file, etc., that may indicate the set of destinations and the set of routes for the transportation system. At block 610, the process 600 may generate a graph based on the set of destinations and the set of routes. For example, the process 600 may use Kruskal's algorithm, Prim's algorithm, etc., to create the graph.

At block 615, the process 600 may update the graph. For example, the process 600 may add edges to the graph, as discussed above. The process 600 may perform the operations, actions, method, etc., illustrated in pseudocode 400 of FIG. 4 to add edges to the graph. The process 600 may also remove edges (e.g., prune) edges in the graph, as discussed above. The process 600 may perform the operations, actions, method, etc., illustrated in pseudocode 500 of FIG. 5 to remove edges from the graph. The process 600 may also replace edges in the graph with other edges, as discussed above. The process 600 may perform the operations, actions, method, etc., illustrated in pseudocode 500 of FIG. 5 to replace edges in the graph.

At block 620, the process 600 may generate a layout for the transportation system based on the graph. For example, after the graph has been generated and updated, the process 600 may generate a map. The map may be generated based on the (updated) graph. For example, the nodes of the graph may represent the destinations of the map and the edges of the graph may represent transportation lines between the destinations of the map. Thus, the layout of the transportation system may indicate how the different destinations may be interconnected with each other via transportation lines.

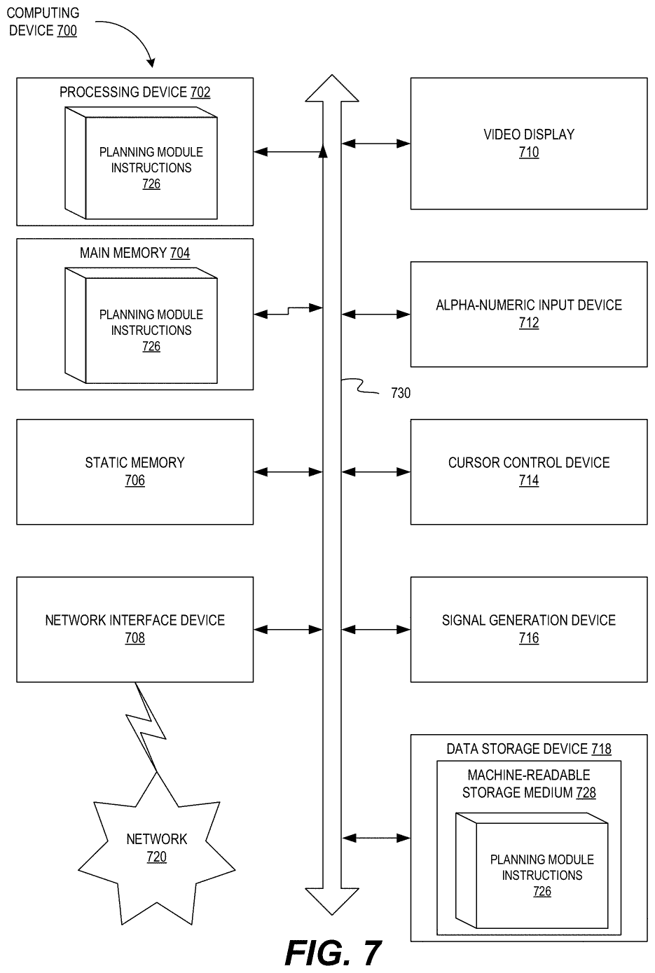

FIG. 7 is a block diagram of an example computing device 700 that may perform one or more of the operations described herein, in accordance with some embodiments. Computing device 700 may be connected to other computing devices in a LAN, an intranet, an extranet, and/or the Internet. The computing device may operate in the capacity of a server machine in client-server network environment or in the capacity of a client in a peer-to-peer network environment. The computing device may be provided by a personal computer (PC), a set-top box (STB), a server, a network router, switch or bridge, or any machine capable of executing a set of instructions (sequential or otherwise) that specify actions to be taken by that machine. Further, while only a single computing device is illustrated, the term “computing device” shall also be taken to include any collection of computing devices that individually or jointly execute a set (or multiple sets) of instructions to perform the methods discussed herein.

The example computing device 700 may include a processing device (e.g., a general purpose processor, a PLD, etc.) 702, a main memory 704 (e.g., synchronous dynamic random access memory (DRAM), read-only memory (ROM)), a static memory 706 (e.g., flash memory and a data storage device 718), which may communicate with each other via a bus 730.

Processing device 702 may be provided by one or more general-purpose processing devices such as a microprocessor, central processing unit, or the like. In an illustrative example, processing device 702 may comprise a complex instruction set computing (CISC) microprocessor, reduced instruction set computing (RISC) microprocessor, very long instruction word (VLIW) microprocessor, or a processor implementing other instruction sets or processors implementing a combination of instruction sets. Processing device 702 may also comprise one or more special-purpose processing devices such as an application specific integrated circuit (ASIC), a field programmable gate array (FPGA), a digital signal processor (DSP), network processor, or the like. The processing device 702 may be configured to execute the operations described herein, in accordance with one or more aspects of the present disclosure, for performing the operations and steps discussed herein.

Computing device 700 may further include a network interface device 708 which may communicate with a network 720. The computing device 700 also may include a video display unit 710 (e.g., a liquid crystal display (LCD) or a cathode ray tube (CRT)), an alphanumeric input device 712 (e.g., a keyboard), a cursor control device 714 (e.g., a mouse) and an acoustic signal generation device 716 (e.g., a speaker). In one embodiment, video display unit 710, alphanumeric input device 712, and cursor control device 714 may be combined into a single component or device (e.g., an LCD touch screen).

Data storage device 718 may include a computer-readable storage medium 728 on which may be stored one or more sets of instructions, e.g., instructions for carrying out the operations described herein, in accordance with one or more aspects of the present disclosure. Instructions 726 implementing a planning module, may also reside, completely or at least partially, within main memory 704 and/or within processing device 702 during execution thereof by computing device 700, main memory 704 and processing device 702 also constituting computer-readable media. The instructions may further be transmitted or received over a network 720 via network interface device 708.

While computer-readable storage medium 728 is shown in an illustrative example to be a single medium, the term “computer-readable storage medium” should be taken to include a single medium or multiple media (e.g., a centralized or distributed database and/or associated caches and servers) that store the one or more sets of instructions. The term “computer-readable storage medium” shall also be taken to include any medium that is capable of storing, encoding or carrying a set of instructions for execution by the machine and that cause the machine to perform the methods described herein. The term “computer-readable storage medium” shall accordingly be taken to include, but not be limited to, solid-state memories, optical media and magnetic media.

Unless specifically stated otherwise, terms such as “requesting,” “determining,” “merging,” “activating,” “transmitting,” “receiving,” or the like, refer to actions and processes performed or implemented by computing devices that manipulates and transforms data represented as physical (electronic) quantities within the computing device's registers and memories into other data similarly represented as physical quantities within the computing device memories or registers or other such information storage, transmission or display devices. Also, the terms “first,” “second,” “third,” “fourth,” etc., as used herein are meant as labels to distinguish among different elements and may not necessarily have an ordinal meaning according to their numerical designation.

Examples described herein also relate to an apparatus for performing the operations described herein. This apparatus may be specially constructed for the required purposes, or it may comprise a general purpose computing device selectively programmed by a computer program stored in the computing device. Such a computer program may be stored in a computer-readable non-transitory storage medium.

The methods and illustrative examples described herein are not inherently related to any particular computer or other apparatus. Various general purpose systems may be used in accordance with the teachings described herein, or it may prove convenient to construct more specialized apparatus to perform the required method steps. The required structure for a variety of these systems will appear as set forth in the description above.

The above description is intended to be illustrative, and not restrictive. Although the present disclosure has been described with references to specific illustrative examples, it will be recognized that the present disclosure is not limited to the examples described. The scope of the disclosure should be determined with reference to the following claims, along with the full scope of equivalents to which the claims are entitled.

As used herein, the singular forms “a”, “an” and “the” are intended to include the plural forms as well, unless the context clearly indicates otherwise. It will be further understood that the terms “comprises”, “comprising”, “includes”, and/or “including”, when used herein, specify the presence of stated features, integers, steps, operations, elements, and/or components, but do not preclude the presence or addition of one or more other features, integers, steps, operations, elements, components, and/or groups thereof. Therefore, the terminology used herein is for the purpose of describing particular embodiments only and is not intended to be limiting.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Although the method operations were described in a specific order, it should be understood that other operations may be performed in between described operations, described operations may be adjusted so that they occur at slightly different times or the described operations may be distributed in a system which allows the occurrence of the processing operations at various intervals associated with the processing.

Various units, circuits, or other components may be described or claimed as “configured to” or “configurable to” perform a task or tasks. In such contexts, the phrase “configured to” or “configurable to” is used to connote structure by indicating that the units/circuits/components include structure (e.g., circuitry) that performs the task or tasks during operation. As such, the unit/circuit/component can be said to be configured to perform the task, or configurable to perform the task, even when the specified unit/circuit/component is not currently operational (e.g., is not on). The units/circuits/components used with the “configured to” or “configurable to” language include hardware--for example, circuits, memory storing program instructions executable to implement the operation, etc. Reciting that a unit/circuit/component is “configured to” perform one or more tasks, or is “configurable to” perform one or more tasks, is expressly intended not to invoke 35 U.S.C. 112, sixth paragraph, for that unit/circuit/component. Additionally, “configured to” or “configurable to” can include generic structure (e.g., generic circuitry) that is manipulated by software and/or firmware (e.g., an FPGA or a general-purpose processor executing software) to operate in manner that is capable of performing the task(s) at issue. “Configured to” may also include adapting a manufacturing process (e.g., a semiconductor fabrication facility) to fabricate devices (e.g., integrated circuits) that are adapted to implement or perform one or more tasks. “Configurable to” is expressly intended not to apply to blank media, an unprogrammed processor or unprogrammed generic computer, or an unprogrammed programmable logic device, programmable gate array, or other unprogrammed device, unless accompanied by programmed media that confers the ability to the unprogrammed device to be configured to perform the disclosed function(s).

The foregoing description, for the purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the embodiments and its practical applications, to thereby enable others skilled in the art to best utilize the embodiments and various modifications as may be suited to the particular use contemplated. Accordingly, the present embodiments are to be considered as illustrative and not restrictive, and the invention is not to be limited to the details given herein, but may be modified within the scope and equivalents of the appended claims.

What is claimed is:

1. A method, comprising:
determining a set of destinations for a transportation system, wherein the first transportation uses a first transportation technology;
determining a set of routes between the set of destinations for the transportation system;
generating a graph based on the set of destinations and the set of routes, wherein:
the graph comprises a set of nodes that represent the set of destinations;
the graph further comprises a set of edges that represent a first subset of the set of routes;
the set of edges are associated with a set of costs;
each cost of the set of costs represents a respective travel time for a respective route when the first transportation technology is used;
updating, by a processing device, the graph based on a second set of costs, wherein each cost of the set second of costs represents a respective travel time between two nodes when a second transportation technology is used; and
generating a layout for the transportation system based on the graph.

2. The method of claim 1, wherein, updating the graph based on a second set of costs comprises:
determining that a first cost associated with a first route is above a second cost associated with the first route, wherein:
the first route is between a first node and a second node;
the first cost is from the first set of costs; and
the second cost is from the second set of costs;
adding one or more edges to the graph, between the first node and the second node.

3. The method of claim 1, wherein, updating the graph based on a second set of costs comprises:
determining whether a first set of edges can be removed from the graph;
in response to determining that the first set of edges can be removed from the graph, removing the first set of edges.

4. The method of claim 1, wherein, updating the graph based on a second set of costs comprises:
determining whether a first set of edges in the graph can be replaced with a second set of edges, wherein the second set of edges have lower costs than the first set of edges;
in response to determine that the first set of edges in the graph can be replaced with the second set of edges, replacing the first set of edges with the second set of edges.

5. The method of claim 1, wherein:
each cost of the first set of costs are based on a travel speed using the first transportation technology for a respective route between two nodes; and
each cost of the second set of costs are based on a travel speed directly between the two nodes using the second transportation technology.

6. The method of claim 1, wherein each cost of the first set of costs are based on a distance for a respective route.

7. The method of claim 1, wherein the first transportation technology is capable of a faster travel speed than the second transportation technology.

8. The method of claim 7, wherein:
the first transportation technology comprises a magnetic levitation transportation system; and
wherein the second transportation technology comprises a high-speed rail technology.

9. The method of claim 1, wherein the layout for the transportation system is generated in a running time that is less than exponential running time.

10. An apparatus, comprising:
a memory configured to store data; and
a processing device, coupled to the memory, the processing device configured to:
determine a set of destinations for a transportation system, wherein the first transportation uses a first transportation technology;
determine a set of routes between the set of destinations for the transportation system;
generate a graph based on the set of destinations and the set of routes, wherein:
the graph comprises a set of nodes that represent the set of destinations;
the graph further comprises a set of edges that represent a first subset of the set of routes;
the set of edges are associated with a set of costs;
each cost of the set of costs represents a respective travel time for a respective route when the first transportation technology is used;
update, by a processing device, the graph based on a second set of costs, wherein each cost of the second set of costs represents a respective travel time between two nodes when a second transportation technology is used; and
generate a layout for the transportation system based on the graph.

11. The apparatus of claim 10, wherein, to update the graph based on a second set of costs the processing device is further configured to:
determine that a first cost associated with a first route is above a second cost associated with the first route, wherein:
the first route is between a first node and a second node;
the first cost is from the first set of costs; and
the second cost is from the second set of costs;
add one or more edges to the graph, between the first node and the second node.

12. The apparatus of claim 10, wherein, to update the graph based on a second set of costs the processing device is further configured to:
determine whether a first set of edges can be removed from the graph;
in response to determining that the first set of edges can be removed from the graph, remove the first set of edges.

13. The apparatus of claim 10, wherein, to update the graph based on a second set of costs the processing device is further configured to:
determine whether a first set of edges in the graph can be replaced with a second set of edges, wherein the second set of edges have lower costs than the first set of edges;
in response to determine that the first set of edges in the graph can be replaced with the second set of edges, replace the first set of edges with the second set of edges.

14. The apparatus of claim 10, wherein:
each cost of the first set of costs are based on a travel speed using the first transportation technology for a respective route between two nodes; and
each cost of the second set of costs are based on a travel speed directly between the two nodes using the second transportation technology.

15. The apparatus of claim 10, wherein each cost of the first set of costs are based on a distance for a respective route.

16. The apparatus of claim 10, wherein the first transportation technology is capable of a faster travel speed than the second transportation technology.

17. The apparatus of claim 16, wherein:
the first transportation technology comprises a magnetic levitation transportation system; and
the second transportation technology comprises a high-speed rail technology.

18. The apparatus of claim 10, wherein the layout for the transportation system is generated in a running time that is less than an exponential running time.

19. A non-transitory computer readable medium having instructions stored thereon that, when executed by a processing device, cause the processing device to:
determine a set of destinations for a transportation system, wherein the first transportation uses a first transportation technology;
determine a set of routes between the set of destinations for the transportation system;
generate a graph based on the set of destinations and the set of routes, wherein:
the graph comprises a set of nodes that represent the set of destinations;
the graph further comprises a set of edges that represent a first subset of the set of routes;
the set of edges are associated with a set of costs;
each cost of the set of costs represents a respective travel time for a respective route when the first transportation technology is used;
update, by a processing device, the graph based on a second set of costs, wherein each cost of the set second of costs represents a respective travel time between two nodes when a second transportation technology is used; and
generate a layout for the transportation system based on the graph.

20. The non-transitory computer readable medium of claim 19, wherein:
each cost of the first set of costs are based on a travel speed using the first transportation technology for a respective route between two nodes; and
each cost of the second set of costs are based on a travel speed directly between the two nodes using the second transportation technology.
